(19) United States
(12) Patent Application Publication
(10) Pub. No.: US 2026/0354255 A1
(43) Pub. Date: Nov. 5, 2026

(54) SEMICONDUCTOR DEVICE AND METHOD FOR MANUFACTURING SEMICONDUCTOR DEVICE

(71) Applicants: KABUSHIKI KAISHA TOSHIBA, Kawasaki-shi, Kanagawa (JP); TOSHIBA ELECTRONIC DEVICES & STORAGE CORPORATION, Kawasaki-shi, Kanagawa (JP)

(72) Inventor: Shuji KAMATA, Himeji Hyogo (JP)

(73) Assignees: KABUSHIKI KAISHA TOSHIBA, Kawasaki-shi, Kanagawa (JP); TOSHIBA ELECTRONIC DEVICES & STORAGE CORPORATION, Kawasaki-shi, Kanagawa (JP)

(21) Appl. No.: 19/487,076

(22) PCT Filed: Apr. 1, 2024
(86) PCT No.: PCT/JP2024/013496

§ 371 Date: Nov. 24, 2025

(30) Foreign Application Priority Data
Sep. 22, 2023 (JP) 2023-156946

(51) Int. Cl. H10W 74/10; H10W 72/00; H10W 72/30; H10W 72/90; H10W 74/47

(52) U.S. Cl. CPC H10W 74/121; H10W 72/07332; H10W 72/352; H10W 72/983; H10W 74/141; H10W 74/147; H10W 74/47

(57) ABSTRACT

A semiconductor device of an embodiment includes: a first metal layer; a semiconductor chip including an upper electrode, a lower electrode, a semiconductor layer provided between the upper electrode and the lower electrode, and a first resin layer provided on the upper electrode and containing a first resin; a second metal layer provided between the first metal layer and the lower electrode and containing silver (Ag) or copper (Cu); a second resin layer covering an outer peripheral portion of the semiconductor chip, having an annular shape, and containing a second resin different from the first resin; and a third resin layer provided between the first resin layer and the second resin layer and containing a third resin different from the first resin and the second resin.

### TECHNICAL FIELD

Embodiments described herein relate generally to a semiconductor device and a method for manufacturing the semiconductor device.

### BACKGROUND ART

In a power semiconductor module, for example, a semiconductor chip is mounted on an insulating substrate. The semiconductor chip is, for example, a metal oxide field effect transistor (MOSFET), an insulated gate bipolar transistor (IGBT), or a diode.

In a power semiconductor module required to operate at a high temperature, for example, when a semiconductor chip and a metal layer on a surface of an insulating substrate are bonded to each other, a bonding layer having high heat resistance is formed by using metal fine particles. The bonding layer is formed by pressing the semiconductor chip against the metal layer at a high temperature.

It is expected to improve a manufacturing yield when a semiconductor chip is mounted on a substrate.

### CITATION LIST

### Patent Literature

Patent Literature 1: JP 5804203 B2

### SUMMARY OF THE INVENTION

### Problem to be Solved by the Invention

An object of the present invention is to provide a semiconductor device that improves a manufacturing yield when mounting a semiconductor chip on a substrate.

### Solution to Problem

### Means for Solving Problem

A semiconductor device of one aspect of the present invention includes: a first metal layer; a semiconductor chip including an upper electrode, a lower electrode, a semiconductor layer provided between the upper electrode and the lower electrode, and a first resin layer provided on the upper electrode and containing a first resin; a second metal layer provided between the first metal layer and the lower electrode and containing silver (Ag) or copper (Cu); a second resin layer covering an outer peripheral portion of the semiconductor chip, having an annular shape, and containing a second resin different from the first resin; and a third resin layer provided between the first resin layer and the second resin layer and containing a third resin different from the first resin and the second resin.

### BRIEF DESCRIPTION OF THE DRAWINGS

FIG. 1 is a schematic view of a semiconductor chip of a semiconductor device of an embodiment.

FIG. 2 is a schematic view of a semiconductor device of an embodiment.

FIG. 3 is an explanatory view of an example of a method for manufacturing a semiconductor device of an embodiment.

FIG. 4 is an explanatory view of an example of a method for manufacturing a semiconductor device of an embodiment.

FIG. 5 is an explanatory view of an example of a method for manufacturing a semiconductor device of an embodiment.

FIG. 6 is an explanatory view of an example of a method for manufacturing a semiconductor device of an embodiment.

FIG. 7 is an explanatory view of an example of a method for manufacturing a semiconductor device of an embodiment.

FIG. 8 is an explanatory view of an example of a method for manufacturing a semiconductor device of an embodiment.

FIG. 9 is an explanatory view of an example of a method for manufacturing a semiconductor device of an embodiment.

### EMBODIMENT(S) FOR CARRYING OUT THE INVENTION

In the present specification, the same or similar members are denoted by the same reference numerals, and redundant descriptions may be omitted.

In the present specification, in order to indicate positional relationships of components and the like, an upward direction in the drawings may be described as “upper”, and a downward direction in the drawings may be described as “lower”. In the present specification, the concepts of “upper” and “lower” do not necessarily indicate a relationship with the direction of gravity.

The type of resin constituting the semiconductor device of the embodiment can be specified by, for example, Fourier Transform Infrared Spectroscopy (FT-IR) or Pyrolysis-Gas Chromatography/Mass Spectrometry.

A semiconductor device of an embodiment includes: a first metal layer; a semiconductor chip including an upper electrode, a lower electrode, a semiconductor layer provided between the upper electrode and the lower electrode, and a first resin layer provided on the upper electrode and containing a first resin; a second metal layer provided between the first metal layer and the lower electrode and containing silver (Ag) or copper (Cu); a second resin layer covering an outer peripheral portion of the semiconductor chip, having an annular shape, and containing a second resin different from the first resin; and a third resin layer provided between the first resin layer and the second resin layer and containing a third resin different from the first resin and the second resin.

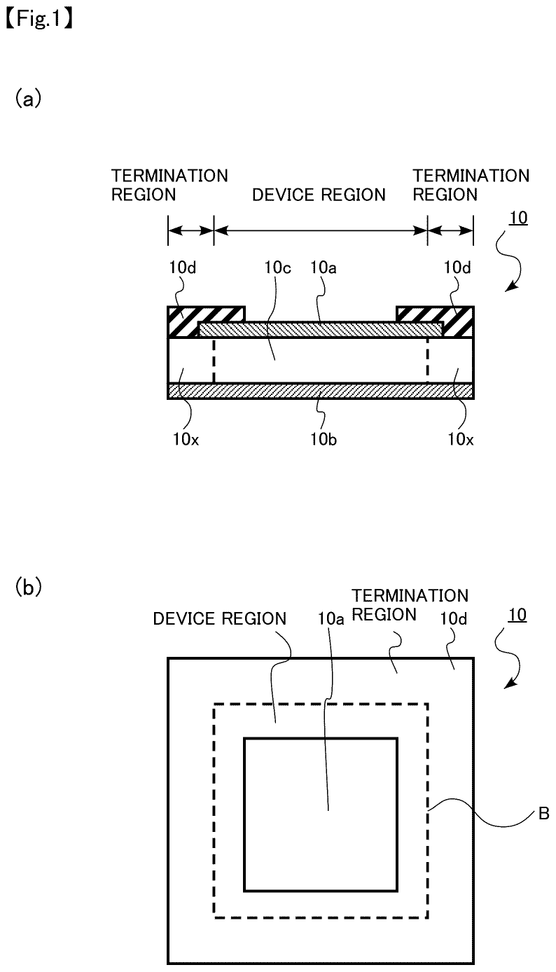

FIGS. 1(a) and 1(b) are schematic views of the semiconductor chip of the semiconductor device of the embodiment. FIG. 1(a) is a cross-sectional view. FIG. 1(b) is a top view.

The semiconductor device of the embodiment is a power semiconductor module 100. In the power semiconductor module 100 of the embodiment, for example, a plurality of semiconductor chips are mounted. The semiconductor chip is, for example, a Schottky barrier diode (SBD).

FIGS. 1(a) and 1(b) are views illustrating a semiconductor chip 10 provided in the power semiconductor module 100 of the embodiment. The semiconductor chip 10 is, for example, an SBD.

The semiconductor chip 10 includes an upper electrode 10a, a lower electrode 10b, a semiconductor layer 10c, and a protective resin layer 10d (first resin layer).

The semiconductor layer 10c is provided between the upper electrode 10a and the lower electrode 10b. The semiconductor layer 10c is, for example, a silicon carbide layer.

The protective resin layer 10d is provided on the upper electrode 10a. The protective resin layer 10d contains a first resin. The first resin includes, for example, polyimide (PI). The protective resin layer 10d is, for example, a polyimide layer.

The semiconductor chip 10 includes a device region and a termination region. The termination region surrounds the device region. The termination region is provided on an outer peripheral portion of the semiconductor chip. The dotted line B in FIG. 1(b) indicates a boundary between the device region and the termination region.

The termination region has a function of relaxing the intensity of an electric field applied to an end portion of the device region and improving the breakdown voltage of the semiconductor chip 10.

In the semiconductor layer 10c in the termination region, a termination structure 10x is formed. The termination structure is, for example, a RESURF structure or a guard ring structure.

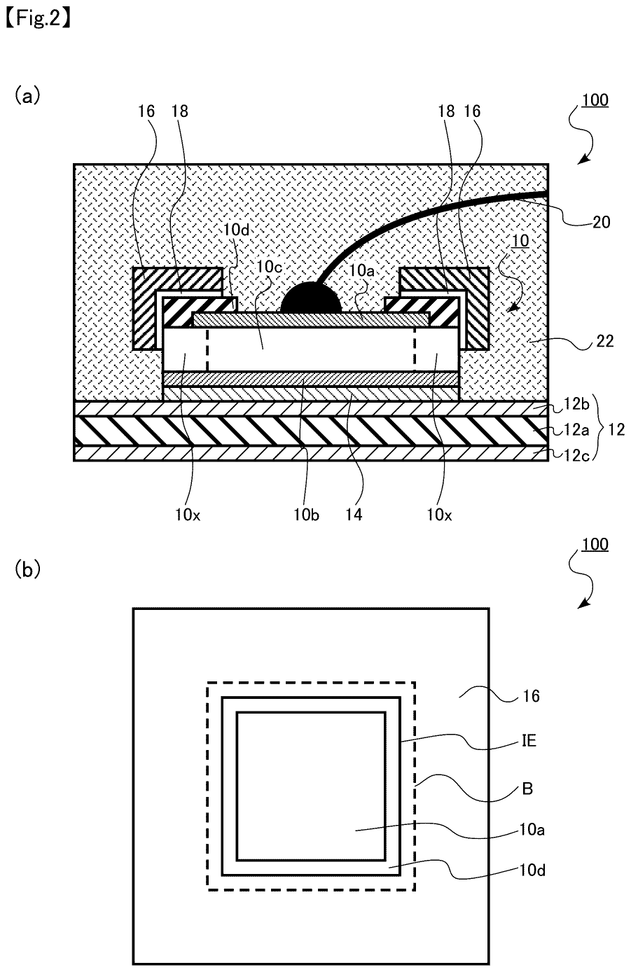

FIGS. 2(a) and 2(b) are schematic views of the semiconductor device of the embodiment. FIG. 2(a) is a cross-sectional view. FIG. 2(b) is a top view. FIGS. 2(a) and 2(b) are views illustrating a part of the power semiconductor module 100.

The power semiconductor module 100 includes a semiconductor chip 10, an insulating substrate 12, a metal bonding layer 14 (second metal layer), a resin frame layer 16 (second resin layer), a resin bonding layer 18 (third resin layer), a bonding wire 20, and a sealing resin layer 22 (fourth resin layer). The insulating substrate 12 includes a ceramic layer 12a, a surface metal layer 12b (first metal layer), and a back surface metal layer 12c.

The insulating substrate 12 is provided under the semiconductor chip 10. The semiconductor chip 10 is mounted on the insulating substrate 12. The insulating substrate 12 has a function of electrically separating the semiconductor chip 10 from a metal base plate (not illustrated) provided under the insulating substrate 12.

The insulating substrate 12 includes the ceramic layer 12a, the surface metal layer 12b, and the back surface metal layer 12c. The ceramic layer 12a is provided between the surface metal layer 12b and the back surface metal layer 12c.

The ceramic layer 12a is, for example, aluminum oxide, aluminum nitride, or silicon nitride. The surface metal layer 12b and the back surface metal layer 12c are, for example, copper.

The metal bonding layer 14 is provided between the insulating substrate 12 and the semiconductor chip 10. The metal bonding layer 14 is provided between the surface metal layer 12b and the lower electrode 10b. The metal bonding layer 14 is in contact with the surface metal layer 12b and the lower electrode 10b.

The metal bonding layer 14 has a function of bonding the insulating substrate 12 and the semiconductor chip 10. The metal bonding layer 14 electrically connects the insulating substrate 12 and the semiconductor chip 10.

The metal bonding layer 14 contains silver (Ag) or copper (Cu). The metal bonding layer 14 is, for example, a silver layer. The metal bonding layer 14 is, for example, a copper layer.

The resin frame layer 16 is provided on the semiconductor chip 10. The resin frame layer 16 covers the outer peripheral portion of the semiconductor chip 10. The resin frame layer 16 covers an upper face and an end face of the semiconductor chip 10. The resin frame layer 16 has an annular shape.

The inner peripheral end (IE in FIG. 2(b) ) of the resin frame layer 16 is provided inside the boundary (B in FIG. 2(b) ) between the device region and the termination region of the semiconductor chip 10. The resin frame layer 16 covers a surface of the termination region of the semiconductor chip 10.

The resin frame layer 16 contains a second resin. The second resin is different from the first resin. The second resin has, for example, a glass transition temperature equal to or higher than 200 °C. The second resin is, for example, polyamide-imide (PAI) or thermoplastic polyimide (TPI).

The resin bonding layer 18 is provided on the Semiconductor chip 10. The resin bonding layer 18 covers the outer peripheral portion of the semiconductor chip 10. The resin bonding layer 18 covers the upper face and the end face of the semiconductor chip 10. The resin bonding layer 18 has an annular shape.

The resin bonding layer 18 is provided between the protective resin layer 10d and the resin frame layer 16. The resin bonding layer 18 is in contact with the protective resin layer 10d and the resin frame layer 16.

The resin bonding layer 18 contains a third resin. The third resin is different from the first resin and the second resin. The third resin has, for example, a glass transition temperature equal to or higher than 200 °C. The third resin is, for example, polyimide silicone.

The bonding wire 20 is connected to the upper electrode 10a. The bonding wire 20 has, for example, a function of electrically connecting an external terminal (not illustrated) and the semiconductor chip 10. The bonding wire 20 is, for example, an aluminum wire or a copper wire.

The sealing resin layer 22 covers the semiconductor chip 10, the insulating substrate 12, the resin frame layer 16, and the bonding wire 20. The sealing resin layer 22 is surrounded by, for example, a resin case (not illustrated).

The sealing resin layer 22 has a function of protecting the semiconductor chip 10, the insulating substrate 12, the resin frame layer 16, and the bonding wire 20. In addition, the sealing resin layer 22 has a function of electrically insulating the semiconductor chip 10, the insulating substrate 12, the resin frame layer 16, and the bonding wire 20.

The sealing resin layer 22 contains a fourth resin. The fourth resin is different from the first resin, the second resin, and the third resin. The fourth resin is, for example, a silicone gel or an epoxy resin.

A method for manufacturing a semiconductor device of an embodiment includes: bonding a resin frame to an outer peripheral portion of a semiconductor chip using an adhesive; forming a bonding layer containing silver fine particles or copper fine particles on a metal layer; placing the semiconductor chip on the bonding layer; placing a resin member inside the resin frame; and pressing the semiconductor chip against the metal layer at a temperature equal to or higher than room temperature using a pressing member from a side of the resin frame and the resin member to bond the metal layer and the semiconductor chip.

Hereinafter, an example of the method for manufacturing a semiconductor device of an embodiment will be described.

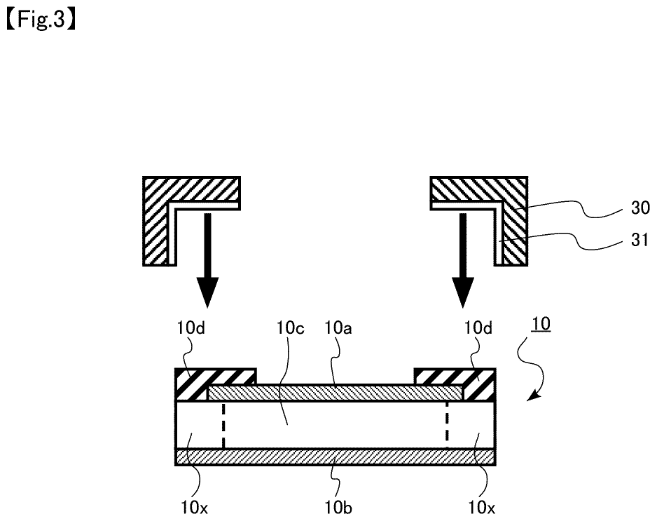

FIGS. 3, 4, 5, 6, 7, 8, and 9 are explanatory views of an example of the method for manufacturing a semiconductor device of the embodiment. FIGS. 3 to 9 are cross-sectional views corresponding to FIG. 2(a).

First, a semiconductor chip 10 is prepared. The semiconductor chip 10 includes an upper electrode 10a, a lower electrode 10b, a semiconductor layer 10c, and a protective resin layer 10d. The semiconductor chip 10 includes a device region and a termination region. The semiconductor layer 10c has a termination structure 10x. The semiconductor chip 10 is, for example, an SBD.

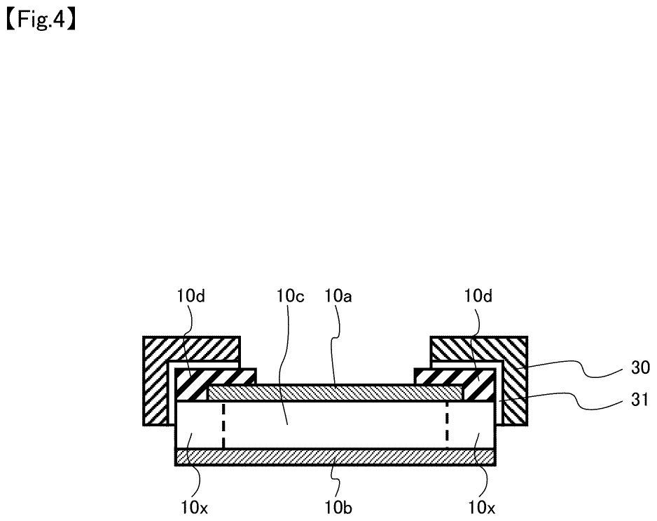

Next, a resin frame 30 is bonded onto the semiconductor chip 10 using an adhesive 31 (FIGS. 3 and 4). The resin frame 30 is bonded to an outer peripheral portion of the semiconductor chip 10. An inner peripheral end of the resin frame 30 is provided, for example, inside a boundary between the device region and the termination region of the semiconductor chip 10.

The resin frame 30 contains a second resin. The second resin is different from the first resin. The second resin has, for example, a glass transition temperature equal to or higher than 200 °C. The second resin is, for example, polyamide-imide (PAI) or thermoplastic polyimide (TPI).

The adhesive 31 contains a third resin. The third resin is different from the first resin and the second resin. The third resin has, for example, a glass transition temperature equal to or higher than 200 °C. The third resin is, for example, polyimide silicone.

The resin frame 30 finally becomes the resin frame layer 16. In addition, the adhesive 31 finally becomes the resin bonding layer 18.

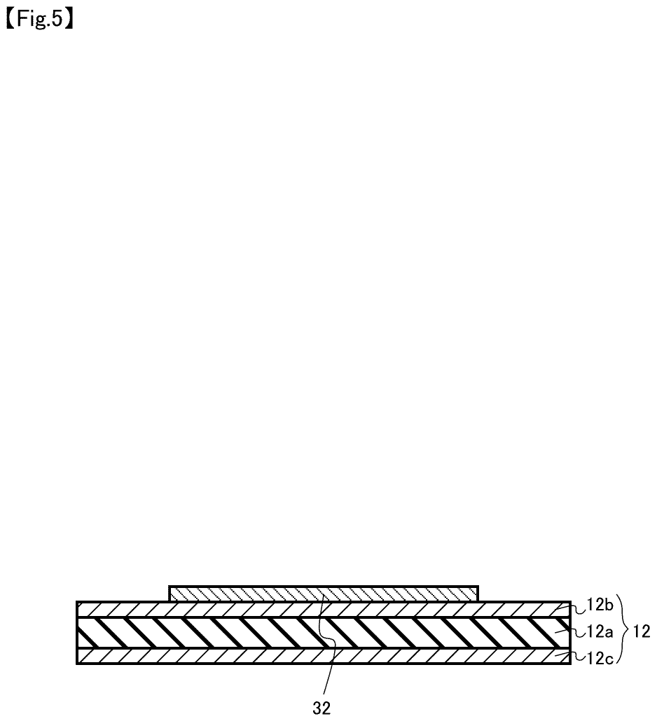

Next, a bonding layer 32 containing silver fine particles or copper fine particles is formed on the insulating substrate 12 (FIG. 5). The insulating substrate 12 includes a ceramic layer 12a, a surface metal layer 12b (metal layer), and a back surface metal layer 12c. The bonding layer 32 is formed on the surface metal layer 12b.

The bonding layer 32 is, for example, a sheet containing silver fine particles or copper fine particles. In addition, the bonding layer 32 is, for example, a paste containing silver fine particles or copper fine particles.

The bonding layer 32 is finally sintered to become the metal bonding layer 14.

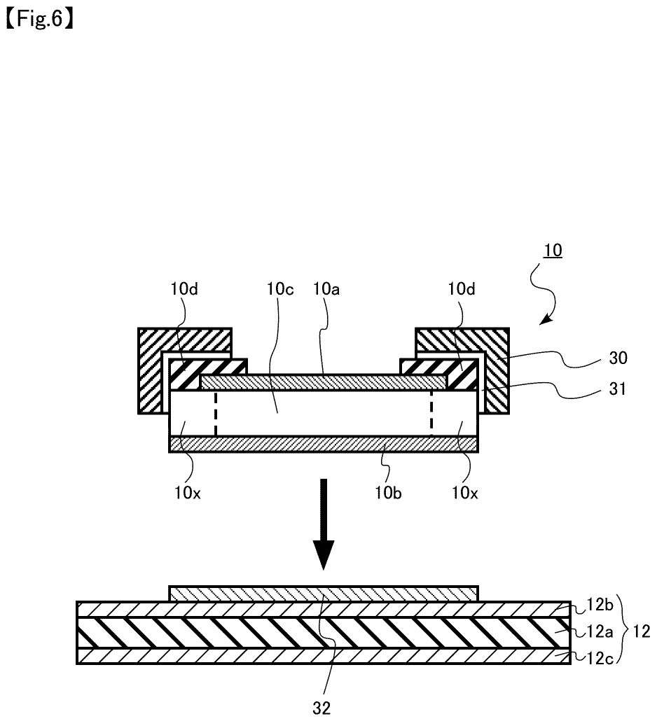

Next, the semiconductor chip 10 is placed on the bonding layer 32 (FIG. 6). The lower electrode 10b of the semiconductor chip 10 is in contact with the bonding layer 32.

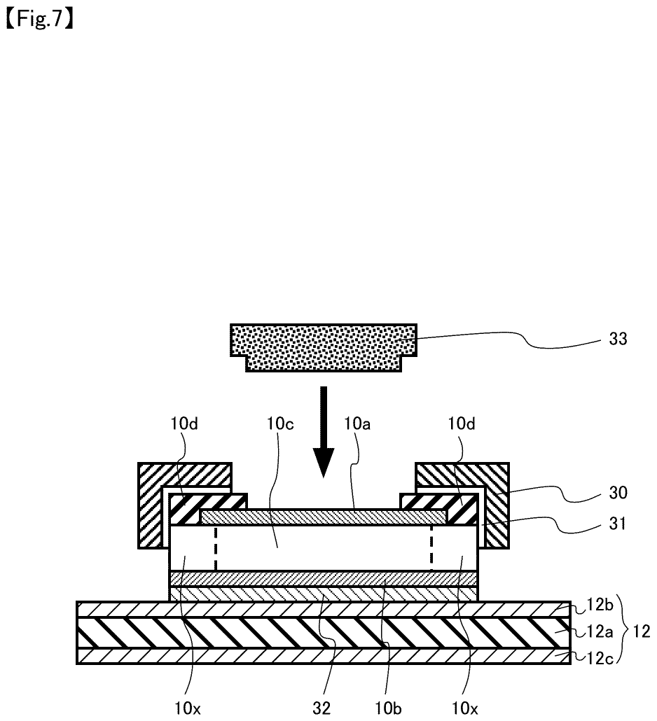

Next, a resin member 33 is placed on the semiconductor chip 10 (FIG. 7). The resin member 33 is placed inside the resin frame 30. The resin member 33 is, for example, a fluororesin.

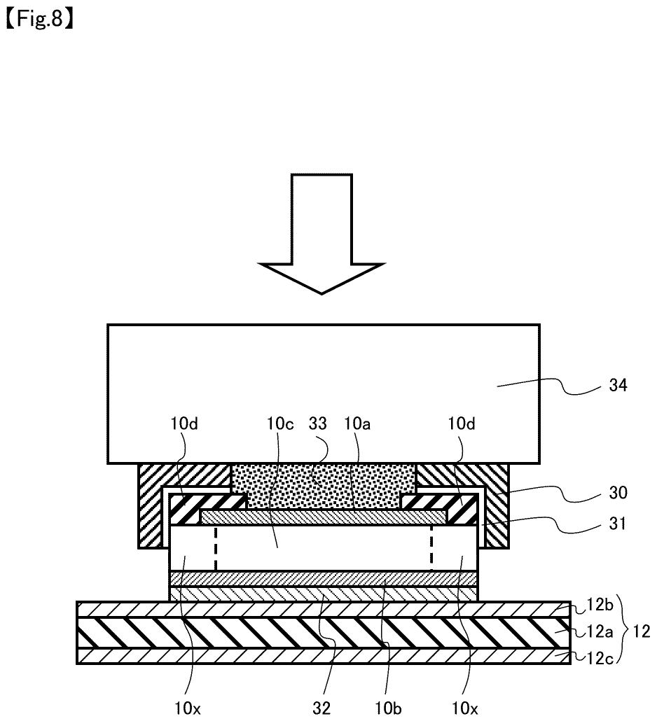

Next, the surface metal layer 12b and the semiconductor chip 10 are bonded (FIG. 8). By sintering the bonding layer 32, the bonding layer 32 is metallized, and the surface metal layer 12b and the semiconductor chip 10 are bonded.

For example, the semiconductor chip 10 is pressed against the surface metal layer 12b using a pressing member 34 from a side of the resin frame 30 and the resin member 33. The pressing of the semiconductor chip 10 is performed, for example, at a temperature higher than room temperature in a heating furnace. For example, the semiconductor chip 10 is heated and pressed at a temperature equal to or higher than 200 °C.

The pressing member 34 is, for example, a metal. When the semiconductor chip 10 is pressed, the resin frame 30 and the resin member 33 serve as cushioning materials and protect the semiconductor chip 10.

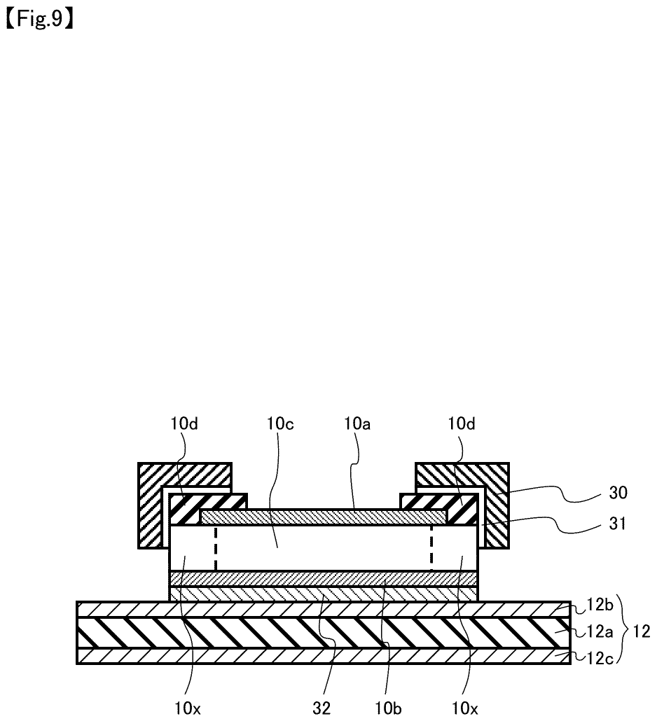

Next, the resin member 33 is removed from above the Semiconductor chip 10 (FIG. 9).

Next, a bonding wire 20 is connected onto the upper electrode 10a. Thereafter, the sealing resin layer 22 covers the semiconductor chip 10, the insulating substrate 12, the resin frame 30, and the bonding wire 20.

The power semiconductor module 100 of the embodiment illustrated in FIG. 2(a) is manufactured by the above manufacturing method.

Next, a function and effect of the semiconductor device of the embodiment will be described.

In a power semiconductor module required to operate at a high temperature, a bonding layer having high heat resistance is formed by using metal fine particles when bonding a semiconductor chip and a metal layer on a surface of an insulating substrate. The bonding layer is formed by pressing the semiconductor chip against the metal layer at a high temperature.

When the semiconductor chip is pressed against the insulating substrate at a high temperature, for example, the semiconductor chip is pressed from the upper face with a resin member serving as a cushioning material interposed between the semiconductor chip and the pressing member. At this time, for example, when a foreign substance exists between the resin member and the semiconductor chip, the foreign substance may be embedded in the surface of the semiconductor chip.

When a foreign substance is embedded in the surface of the semiconductor chip, for example, a leakage current due to the foreign substance may occur in the semiconductor chip. In addition, when a foreign substance is embedded in the surface of the semiconductor chip, for example, the electric field intensity distribution in the semiconductor chip may change, and the breakdown voltage characteristics of the semiconductor chip may degrade. Therefore, when a foreign substance is embedded in the surface of the semiconductor chip, there is a possibility that an initial yield of the semiconductor module is lowered and a reliability yield is lowered.

In particular, the termination region provided in the outer peripheral portion of the semiconductor chip is a region where the electric field intensity in the semiconductor chip increases. Therefore, when a foreign substance is embedded in the surface of the termination region of the semiconductor chip, there is a high possibility that, in particular, a decrease in initial yield and a decrease in reliability yield of the semiconductor module become apparent.

In the method for manufacturing a semiconductor device of the embodiment, the surface of the outer peripheral portion of the semiconductor chip 10 is covered with the resin frame 30 when the semiconductor chip 10 is pressed at a high temperature. Therefore, when the semiconductor chip 10 is pressed at a high temperature, it is possible to suppress a foreign substance from being embedded in the surface of the termination region of the semiconductor chip 10. Therefore, it is possible to suppress a decrease in initial yield and a decrease in reliability of the power semiconductor module 100. In other words, the manufacturing yield of the power semiconductor module 100 can be improved. In addition, the power semiconductor module 100 of the embodiment has a structure that facilitates improvement in manufacturing yield.

In the method for manufacturing a semiconductor device of the embodiment, even when there is a foreign substance between the surface of the outer peripheral portion of the semiconductor chip 10 and the resin frame 30, the foreign substance is fixed to the adhesive 31 in advance. Therefore, when the semiconductor chip 10 is pressed at a high temperature, it is possible to suppress a foreign substance from being embedded in the surface of the termination region of the semiconductor chip 10.

From the viewpoint of suppressing a decrease in initial yield and a decrease in reliability of the power semiconductor module 100, it is preferable that the surface of the termination region of the semiconductor chip 10 is completely covered with the resin frame 30. Therefore, it is preferable that the inner peripheral end of the resin frame 30 is provided, for example, inside the boundary between the device region and the termination region of the semiconductor chip 10.

It is preferable that the second resin contained in the resin frame 30 has high heat resistance from the viewpoint of suppressing degradation in characteristics of the resin frame 30 when the semiconductor chip 10 is pressed at a high temperature. A glass transition temperature of the second resin is preferably equal to or higher than 200 °C, and more preferably equal to or higher than 250 °C.

When the semiconductor chip 10 is pressed at a high temperature, it is preferable that the third resin contained in the adhesive 31 has high heat resistance from the viewpoint of suppressing degradation in characteristics of the adhesive 31. A glass transition temperature of the third resin is preferably equal to or higher than 200 °C, and more preferably equal to or higher than 250 °C.

As described above, according to the embodiment, it is possible to realize a semiconductor device and a method for manufacturing a semiconductor device that improve the yield when mounting a semiconductor chip on a substrate.

In the embodiment, the case where the SBD is used as the semiconductor chip has been described as an example, but the semiconductor chip is not limited to the SBD. For example, other transistors and diodes such as a MOSFET, an IGBT, and a PIN diode can be applied. A combination of a transistor and a diode can also be applied.

In the embodiment, the power semiconductor module has been described as an example of the semiconductor device, but the semiconductor device may be a discrete device on which one semiconductor chip is mounted.

In the embodiment, the case where the bonding wire 20 and the sealing resin layer 22 are provided has been described as an example, but it is also possible to adopt a configuration in which the bonding wire 20 and the sealing resin layer 22 are not provided.

In the embodiment, the case where the semiconductor layer 10c is a silicon carbide layer has been described as an example, but the semiconductor layer 10c may be another Semiconductor layer, for example, a silicon layer or a nitride semiconductor layer.

Although some embodiments of the present invention have been described, these embodiments have been presented as examples and are not intended to limit the scope of the invention. These novel embodiments can be implemented in various other forms, and various omissions, substitutions, and modifications can be made without departing from the gist of the invention. For example, a component of one embodiment may be replaced with or modified by a component of another embodiment. These embodiments and modifications thereof are included in the scope and gist of the invention, and are included within the scope of the invention described in the claims and equivalents thereof.

### REFERENCE SIGNS LIST

10 Semiconductor chip
10a Upper electrode
10b Lower electrode
10c Semiconductor layer
10d Protective resin layer (first resin layer)
12b Surface metal layer (first metal layer, metal layer)
14 Metal bonding layer (second metal layer)
16 Resin frame layer (second resin layer)
18 Resin bonding layer (third resin layer)
22 Sealing resin layer (fourth resin layer)
30 Resin frame
31 Adhesive
32 Bonding layer
33 Resin member
34 Pressing member
100 Power semiconductor module (semiconductor device)

1. A semiconductor device comprising:
a first metal layer;
a semiconductor chip including an upper electrode, a lower electrode, a semiconductor layer provided between the upper electrode and the lower electrode, and a first resin layer provided on the upper electrode and containing a first resin;
a second metal layer provided between the first metal layer and the lower electrode and containing silver (Ag) or copper (Cu);
a second resin layer covering an outer peripheral portion of the semiconductor chip, having an annular shape, and containing a second resin different from the first resin; and
a third resin layer provided between the first resin layer and the second resin layer and containing a third resin different from the first resin and the second resin.

2. The semiconductor device according to claim 1, wherein the semiconductor chip includes a device region and a termination region surrounding the device region, and an inner peripheral end of the second resin layer is provided inside a boundary between the device region and the termination region.

3. The semiconductor device according to claim 1, wherein the second resin layer and the third resin layer cover an upper face and a side face of the semiconductor chip.

4. The semiconductor device according to claim 1, wherein the third resin layer is in contact with the first resin layer and the second resin layer.

5. The semiconductor device according to claim 1, further comprising a fourth resin layer containing a fourth resin different from the first resin, the second resin, and the third resin, and covering the first metal layer, the semiconductor chip, and the second resin layer.

6. The semiconductor device according to claim 1, wherein the semiconductor layer is a silicon carbide layer.

7. The semiconductor device according to claim 1, wherein the first resin is polyimide.

8. The semiconductor device according to claim 1, wherein a glass transition temperature of the second resin is equal to or higher than 200 °C.

9. The semiconductor device according to claim 1, wherein the second resin is polyamide-imide or thermoplastic polyimide.

10. The semiconductor device according to claim 1, wherein a glass transition temperature of the third resin is equal to or higher than 200 °C.

11. The semiconductor device according to claim 1, wherein the third resin is polyimide silicone.

12. The semiconductor device according to claim 5, wherein the fourth resin is a silicone gel or an epoxy resin.

13. A method for manufacturing a semiconductor device, the method comprising:
bonding a resin frame to an outer peripheral portion of a semiconductor chip using an adhesive;
forming a bonding layer containing silver fine particles or copper fine particles on a metal layer;
placing the semiconductor chip on the bonding layer;
placing a resin member inside the resin frame; and
pressing the semiconductor chip against the metal layer at a temperature higher than room temperature using a pressing member from a side of the resin frame and the resin member to bond the metal layer and the semiconductor chip.

14. The method for manufacturing a semiconductor device according to claim 13, wherein the temperature is equal to or higher than 200 °C.

15. The method for manufacturing a semiconductor device according to claim 13, wherein the semiconductor chip includes a device region and a termination region surrounding the device region, and
when the resin frame is bonded to the semiconductor chip, an inner peripheral end of the resin frame is provided inside a boundary between the device region and the termination region.

16. The method for manufacturing a semiconductor device according to claim 13, wherein the resin frame contains polyamide-imide or thermoplastic polyimide.

17. The method for manufacturing a semiconductor device according to claim 13, wherein the adhesive includes polyimide silicone.
